(19) United States
(12) Patent Application Publication
(10) Pub. No.: US 2026/0236536 A1
(43) Pub. Date: Aug. 13, 2026

(54) LAZY MATCHING WITH REDUCED LATENCY FOR DICTIONARY-BASED COMPRESSION

(71) Applicant: MaxLinear, Inc., Carlsbad, CA (US)

(72) Inventors: Pinaki Shankar Chanda, San Diego, CA (US); Siddhant Baldota, San Diego, CA (US); Bin Wu, Hangzhou (CN)

(73) Assignee: MaxLinear, Inc., Carlsbad, CA (US)

(21) Appl. No.: 19/540,481

(22) Filed: Feb. 13, 2026

Related U.S. Application Data
(60) Provisional application No. 63/758,269, filed on Feb. 13, 2025.

(51) Int. Cl. G06F 16/903; H03M 7/30

(52) U.S. Cl. CPC G06F 16/90344; H03M 7/3086

(57) ABSTRACT

A method may include obtaining input symbols and a hash table. The method may also include storing the input symbols in a first buffer at a current coding position, and processed input symbols in a second buffer. The method may further include defining a plurality of delayed match window (DMW) offsets, comprising a highest DMW offset and at least one lower DMW offset. The method may also include performing a substring match search using the input symbols, the processed input symbols, and the highest DMW offset, to determine one or more candidate matches. The method may further include outputting a result from the substring match search corresponding to a determination associated with the one or more candidate matches.

### CROSS REFERENCE TO RELATED APPLICATIONS

This U.S. Patent application claims priority to U.S. Provisional Patent Application No. 63/758,269, titled “LAZY MATCHING ALGORITHM USING A ROLLING HASH,” and filed on Feb. 13, 2025, the disclosure of which is hereby incorporated by reference in its entirety.

### TECHNICAL FIELD

This disclosure relates to lossless data compression, and more specifically, to dictionary-based lossless data compression.

### BACKGROUND

Unless otherwise indicated herein, the materials described herein are not prior art to the claims in the present application and are not admitted to be prior art by inclusion in this section.

Data compression may be lossy or lossless. In lossless compression, data compression algorithms (or “compression algorithms”) may reduce the size of data by identifying and removing redundancies in the data. Further, information content included in the data may not be removed, such that when a decompression operation may be applied to the compressed data, the decompressed data may be restored to be the same as the data before compression. Many data transform accelerators (DTAs), computational storage devices (CSDs), data processing units (DPUs), network interface controllers (NICs), central processing units (CPUs), and field-programmable gate arrays (FPGAs) used in storage or cryptographic appliances, use lossless compression methods.

Many lossless data compression techniques may use dictionary-based compression methods that may extract substrings from the original data string. The substrings may be variable length or fixed length, and the substrings may be used to index a dictionary that may map the substrings into tokens. When the tokens can be represented using reduced number of bits relative to the substrings the tokens are mapped from, data reduction may be achieved. Many texts may not be a random sequence of symbols and a substring of symbols occurring in the input data may be more likely to appear again in the input data. In instances in which the tokens in the dictionary are references to previous occurrences of the substrings, the tokens may be represented using a reduced number of bits that would otherwise be required to represent original substring, such that data reduction may be achieved.

Many widely used dictionary-based compression methods may build the dictionary in an adaptive fashion using a sliding window on already processed symbols. For example, the LZ77 compression algorithm that may be used in LZ4, LZS, Deflate, GZIP, ZLIB, and/or XP10 may utilize an adaptive dictionary as described. The compression algorithm may maintain a history buffer that contains input data already processed by the compression algorithm. The history buffer may operate as a dictionary that may be built adaptively. For example, to process new input data contained in a look-ahead buffer, a pointer may be moved back through the history buffer until a match (e.g., a matched symbol) is found in the history buffer with the first symbol of the new input data included in the look-ahead buffer. Once the match is found, a next symbol in the look-ahead buffer may be compared with a next symbol in history buffer, where the next symbol in the history buffer may be located adjacent to the matched symbol, to determine if additional matches may be obtained. The matching process continues comparing subsequent symbols from the look-ahead buffer with the consecutive symbols in the history buffer until the match ends. In this fashion, the compression algorithm searches the entire history buffer to determine the longest substring match for a substring in the look-ahead buffer.

Once the longest match is found, the compression algorithm encodes the longest match with a <distance, length> pair. Distance may be the distance of the beginning of the longest matched substring in the history buffer from the beginning of the look-ahead buffer. Length may be the length of the longest substring match. Different definitions of distance may be considered, such as if distance indicates the location of the substring in the history buffer. Once a substring in the look-ahead buffer is matched, the substring slides into the front of the history buffer from the look-ahead buffer. In instances in which the history buffer is full, the oldest data in the tail of the history buffer may be discarded. In instances in which there is no match, the symbol in the look-ahead buffer may be emitted as a literal token. Some dictionary-based compression algorithms may create a cache of recently used <distance, length> pairs in a look up table and instead of using <distance, length> pair as a token directly, the compression algorithm may use an index in the look-up table associated with the <distance, length> pair to increase compression ratio (commonly known as Move to Front (MTF) coding). Alternatively, or additionally, individual distance and/or individual length values may be cached.

Some dictionary-based methods may improve a compression ratio by using a lazy evaluation technique, where the compression ratio may be a ratio of a size of the input data relative to a size of the compressed data. After finding the longest substring match using substrings from the beginning of the look-ahead buffer, the compression algorithm may consider a longest substring match, skipping the first symbol of the look-ahead buffer and starting a matching process from the second symbol of the look-ahead buffer with the substrings in the history buffer.

If a longer match is found, the compression algorithm emits the first symbol in look-ahead buffer as a literal token and a subsequent substring match may be emitted as <distance, length> pair token. Otherwise, the compression algorithm may emit the first longest substring match as <distance, length> pair token. As such, the compression algorithm may consider multiple candidate substrings for longest substring match, while skipping a first few symbols (instead of just one symbol) one at a time from the beginning of the look-ahead buffer and longest substring match may be selected from the candidate substrings. Such compression algorithm may be commonly called lazy evaluation or lazy matching. Alternatively, or additionally, the number of symbols the substring match process can defer from the beginning of look-ahead buffer (to select a substring for match) may be called a lazy match window or a delayed match window. For example, a delayed match window value of two may indicate a longest substring match may be considered among candidates of substring matches i) from the beginning of the look-ahead buffer (including the first symbol therein), ii) skipping the first symbol, and ii) also skipping the first two symbols. Larger value lazy match windows may improve compression ratio at the expense of encode latency and/or computational complexity.

When compressing a small data block, there may not be enough history or a sufficiently populated dictionary to use some of the compression algorithms described. In such instances, some compression algorithms may use static pre-shared dictionaries. Alternatively, or additionally, some compression algorithms may use a static pre-initialized dictionary, where the pre-initialized dictionary may be referenced at any time while scanning the input data for a substring match.

Once the input data is converted to a set of tokens (e.g., <distance, length> pairs, index in dictionary, literals, etc.), a variable length coding algorithm, such as Huffman code, may be used to encode the tokens. The Huffman code may use fixed codebooks, and/or constructed codebooks based on frequency of occurrence of the different tokens encountered (also known as retrospective or dynamic coding), that may be generated during the compression process. Multiple codebooks may be used for the same alphabets in the same compressed data block (as in context modeling). Alternatively, or additionally, asymmetric numeral system (ANS) may be used instead of Huffman code.

The subject matter claimed in the present disclosure is not limited to implementations that solve any disadvantages or that operate only in environments such as those described above. Rather, this background is only provided to illustrate one example technology area where some embodiments described in the present disclosure may be practiced.

### SUMMARY

In an example embodiment, a method may include obtaining input symbols and a hash table. The method may also include storing the input symbols in a first buffer at a current coding position, and processed input symbols in a second buffer. The method may further include defining a plurality of delayed match window (DMW) offsets, comprising a highest DMW offset and at least one lower DMW offset. The method may also include performing a substring match search using the input symbols, the processed input symbols, and the highest DMW offset, to determine one or more candidate matches. The method may further include outputting a result from the substring match search corresponding to a determination associated with the one or more candidate matches.

In another embodiment, a system may include a processor and a memory. The memory may be operable to store instructions that, when executed by the processor, may cause the computing system to obtain input symbols and a hash table. The computing system may also be operable to store the input symbols in a first buffer at a current coding position, and processed input symbols in a second buffer. The computing system may further be operable to define a plurality of delayed match window (DMW) offsets, comprising a highest DMW offset and at least one lower DMW offset. The computing system may also be operable to perform a substring match search using the input symbols, the processed input symbols, and the highest DMW offset, to determine one or more candidate matches. The computing system may further be operable to output a result from the substring match search corresponding to a determination associated with the one or more candidate matches.

The objects and advantages of the embodiments will be realized and achieved at least by the elements, features, and combinations particularly pointed out in the claims.

Both the foregoing general description and the following detailed description are given as examples and are explanatory and not restrictive of the invention, as claimed.

### DESCRIPTION OF DRAWINGS

Example implementations will be described and explained with additional specificity and detail using the accompanying drawings in which:

FIGS. 1A-1B illustrate an example flowchart of a lazy matching algorithm for dictionary-based compression;

FIG. 2 illustrates a flowchart of an example method for a lazy matching algorithm for dictionary-based compression; and

FIG. 3 illustrates an example computing device.

### DETAILED DESCRIPTION

Various implementations exist for compressing data, and each of them may vary in a compression ratio of the input data, where the compression ratio may be a ratio of a size of the input data relative to a size of the compressed data. In many instances, improvements to the compression ratio in a particular compression operation may be at the expense of increased computational complexity and/or increased latency in the compression operation. Some prior approaches may use a lazy matching data compression operation, which may be computationally expensive and/or which may cause increases in the latency of the compression operation.

Lazy matching may use multiple searches in a history buffer or the dictionary (or just “history buffer”) which may make lazy matching computationally expensive and/or increase the latency of the compression operation. As such, more CPU cycles may be used when implemented in software on a CPU. When lazy matching is implemented on hardware (such as reconfigurable hardware such as FPGA (Field Programmable Gate Array) or ASIC (Application Specific Integrated Circuits), the lazy matching operation may use more clock cycles and/or more hardware resources (e.g., circuits) resulting in higher power consumption.

Aspects of the present disclosure address these and other limitations by implementing a lazy matching algorithm in hardware or in software that may improve on computational complexity, reduce consumption of computational resources, such as CPU cycles on a processor or clock cycles, and/or reduce power consumption to process data in a hardware-based implementation. Aspects of the present disclosure may also improve throughput and/or latency of the data compression operation. In such implementations, the lazy matching algorithm may compare strings from a look-ahead buffer to a history buffer to obtain substring matches. The lazy matching algorithm may also extend the substring matches to include additional symbols without performing additional scans of the history buffer, such that the computational expense and/or the latency associated with the lazy matching algorithm may be reduced, compared to other lazy matching algorithms and/or other data compression operations.

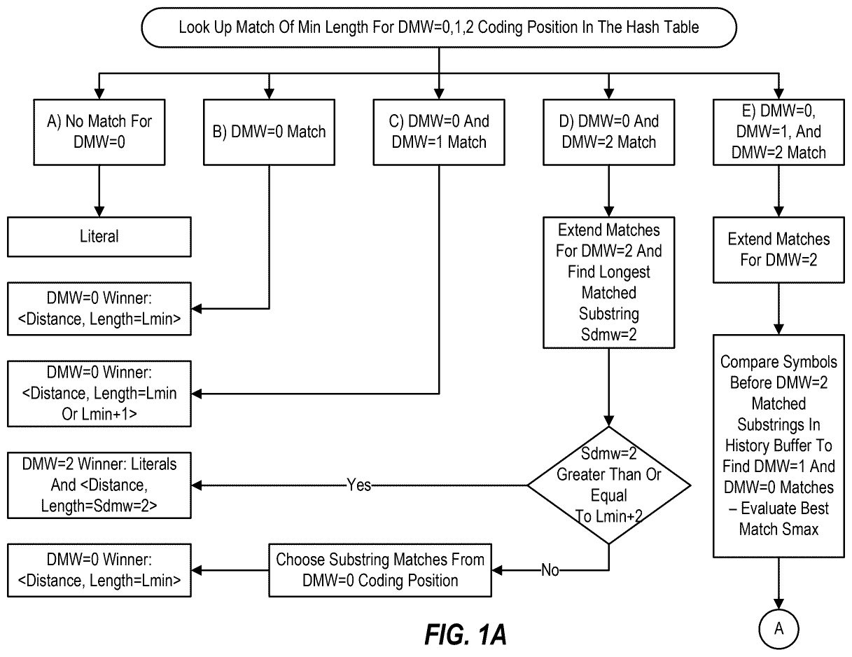

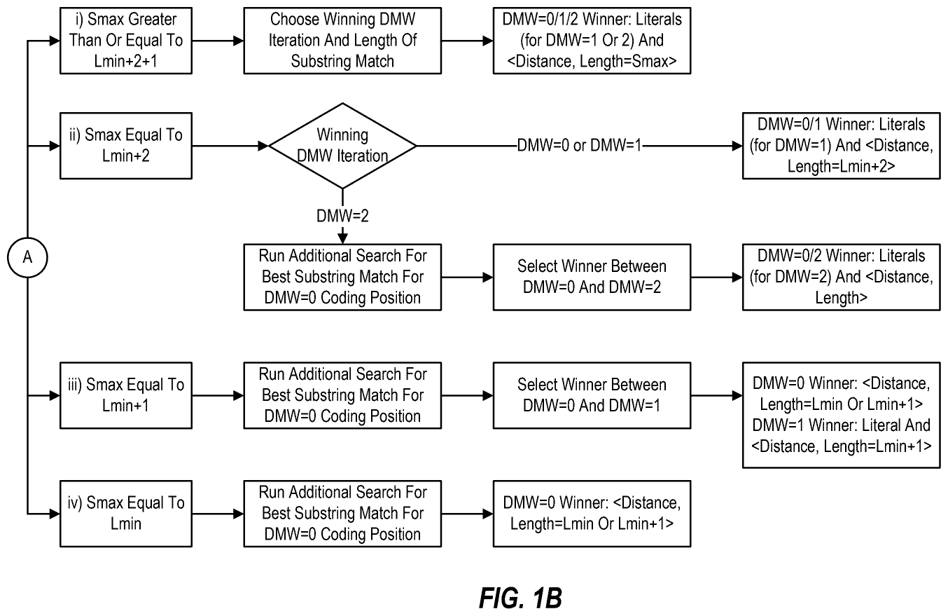

Illustrated in FIGS. 1A and 1B is a flowchart of a lazy matching algorithm using a rolling hash for data compression. Further, the following description of the algorithm may be with respect to the illustrated flowchart of FIGS. 1A and 1B. The algorithm described herein may attempt to obtain matches in reverse delayed matching window (DMW) iteration order (e.g., from higher iterations to lower iterations), may identify extensions of substring matches in higher DMW iterations, and/or may use the substring match extensions to inform subsequent lower DMW iterations. In some instances, suffixes of substring matches found in lower DMW iterations may contain substring matches from higher DMW iterations. In some instances, the suffix of each substring match in DMW=0 iteration (whose length is greater than or equal to 1 plus a minimum length threshold, (min) may correspond to a substring match in higher DMW=1 iteration, and so on. A substring match in DMW=n iteration can then be extended to substring matches in DMW=n-1 iteration by comparing the symbol before the matched substrings in the look-ahead buffer with the symbol preceding the matched substring (from DMW=n iteration) in the history buffer.

In instances in which there is one or more than one match for multiple DMW iterations (e.g., DMW=0, 1, or 2), the winner may be selected using one or more rules described herein. The length of best substring matches in DMW=0, 1, 2 iterations may be denoted as S_{DMW=0}, S_{DMW=1}, S_{DMW=2}, respectively. The DMW=2 iteration may win when S_{DMW=2}>S_{DMW=1}+1 and S_{DMW=2}>S_{DMW=0}+2. The DMW=1 iteration may win over the DMW=0 iteration when S_{DMW=1}>S_{DMW=0}+1. Described herein is an algorithm for DMW length 2 without loss of generality. This description can easily be extended for any DMW length.

A first algorithm step may utilize a rolling hash technique to identify potential matches between a substring in the look-ahead buffer and the history buffer. Hash values for substrings of length lₘᵢₙ in the history buffer are stored in a hash table with their positions. A rolling hash function is updated as new symbols from the look-ahead buffer are encoded, and these new symbols are moved into the history buffer. The updated hash values are then computed for the new symbols in the history buffer and added to the hash table with their corresponding positions.

The hash function may be operable to compute hash values for lₘᵢₙ symbols for various DMW iterations, such as a DMW=0 iteration, a DMW=1 iteration, and/or a DMW=2 iteration (e.g., for the substrings of length lₘᵢₙ starting at coding position (CP) CP, CP+1, and CP+2, respectively, in the look-ahead buffer). As the coding position is updated after encoding one or more symbols from the look-ahead buffer, the rolling hash values may also be updated accordingly. The coding position may be a first position in the look-ahead buffer.

The hash values for the lₘᵢₙ symbols corresponding to coding positions of the DMW=0, 1, and 2 iterations may be looked up in a hash table. The hash table may store the hash values of substrings of length lₘᵢₙ in the history buffer, including the positions of the hash values. To avoid a false positive hash match, symbols may be compared after a match may be identified. Based on these lookups, decisions may be made (as outlined in Table 1) to guide the next steps of the algorithm. Such a process may utilize the reverse DMW iteration technique to efficiently extend the search, predicting the maximum match length and the necessary DMW iterations.

TABLE 1
Decision taken based on hash look up for lₘᵢₙ symbols

| | | | | | DMW |
|---|---|---|---|---|---|
| | | | | | iteration |
| | DMW = | DMW = | DMW = | Longest | producing |
| | 0 hash | 1 hash | 2 hash | match | longest |
| Case | match | match | match | Length | match |
| a | No | Don't care | | <lₘᵢₙ | — |
| b | Yes | No | No | lₘᵢₙ for | DMW 0 |
| | | | | DMW = | |
| | | | | 0 iteration | |
| c | Yes | Yes | No | lₘᵢₙ + 1 for | DMW 0 |
| | | | | DMW = | |
| | | | | 0 iteration | |
| | | | | and lₘᵢₙ for | |
| | | | | DMW = | |
| | | | | 1 iteration | |
| d | Yes | No | Yes | lₘᵢₙ for | DMW 0 or |
| | | | | DMW = | 2 |
| | | | | 0 and ≥ lₘᵢₙ | |
| | | | | for DMW = | |
| | | | | 2 iteration | |
| e | Yes | Yes | Yes | ≥lₘᵢₙ for | DMW 0, |
| | | | | DMW = | 1, or 2 |
| | | | | 0, 1, 2 | |
| | | | | iterations | |

According to case ‘a’ in Table 1, in instances in which no hash match is found for the DMW=0 iteration, a literal may be emitted, and the second step (described herein) may be skipped. The symbol from the current coding position (CP) may then be moved into the history buffer, and the rolling hash function may compute the hash value for the new substring, and may add the computed hash value to the hash table.

According to case ‘b’ in Table 1, in instances in which a hash match is found for the DMW=0 iteration, but not for the DMW=1 and 2 iterations, the maximum match length may be lₘᵢₙ. In instances in which a longer match is found in the DMW=0 iteration, a match of at least lₘᵢₙ may be in the DMW=1 iteration. In instances in which there are multiple matches in the DMW=0 iteration, the closest match to the current position may be chosen, and the <distance, length (=lₘᵢₙ)> pair may be passed to the next coding stage, and the second step described herein may be skipped.

According to case ‘c’ in Table 1, in instances in which a match is found for the DMW=0 iteration and the DMW=1 iteration, but not the DMW=2 iteration, the maximum match length may be lₘᵢₙ+1 for the DMW=0 iteration and may be lₘᵢₙ for the DMW=1 iteration. Alternatively, or additionally, a match of at least lₘᵢₙ may be present in the DMW=2 iteration. The DMW=0 iteration match may be chosen and the length may be either lₘᵢₙ or lₘᵢₙ+1. The hash table may be used to find the lₘᵢₙ matches in the DMW=0 iteration, and the next symbol in the history buffer may be checked against symbol in look-ahead buffer at the position CP+lₘᵢₙ to identify lₘᵢₙ+1 matches. The closest match to the current coding position may be selected, and the <distance, length (=lₘᵢₙ or lₘᵢₙ+1)> pair may be passed to the next stage, and the second step described herein may be skipped.

According to case ‘d’ in Table 1, in instances in which a match is found for the DMW=0 iteration and the DMW=2 iteration, but not the DMW=1 iteration, the match length for the DMW=0 iteration may be limited to lₘᵢₙ, while the match length for the DMW=2 iteration may be ≥lₘᵢₙ. In such instances, the algorithm may proceed to the second algorithm step described herein.

According to case ‘e’ in Table 1, in instances in which hash matches are found for the DMW=0, 1 and 2 iterations, the algorithm may proceed to the second algorithm step described herein. In cases ‘a,’ ‘b,’ and ‘c,’ the second step may not be necessary and/or may be skipped to speed up execution of the algorithm.

As part of the second algorithm step, substring matching may begin at coding positions of higher DMW iterations, where the results may be used to find matches in lower DMW iterations. Regarding case ‘d’ described herein, for the matches found for symbols from coding position of the DMW=2 iteration from the hash table (where lₘᵢₙ symbols from coding position CP+2 in the look-ahead buffer match those in the history buffer) in the first algorithm step, the positions of the matched substrings of length lₘᵢₙ within the history buffer may be examined. In some instances, the symbols following examined substrings in the history buffer may be compared with symbols in the look-ahead buffer, starting from coding position CP+2+lₘᵢₙ, to extend the matches. In some instances, the match with the longest substring may be selected. In instances in which there is a tie, the match closest to the coding position may be selected.

In instances in which the length of the extended match for symbols from coding position CP+2+lₘᵢₙ is ≥ lₘᵢₙ+2, the DMW=0 iteration substring search may not be considered as the maximum substring match in the DMW=0 iteration may be limited to lₘᵢₙ. In such instances, the result may be output to a next coding stage as two literals and a <distance, length> pair.

In instances in which the length of the substring match in the DMW=2 iteration is less than lₘᵢₙ+2, the DMW=0 iteration may be favored. In such instances, the substring matches of length lₘᵢₙ starting at the CP from hash table may be used, as performed in the first algorithm step. From the history buffer, the match closest to the CP may be selected, in case of a tie. In such instances, the result may be output as a <distance, length (=lₘᵢₙ)> pair.

Regarding case ‘e’ described herein, for the matches found for symbols from coding position of the DMW=2 iteration from the hash table (e.g., where lₘᵢₙ symbols from the CP+2 in the look-ahead buffer match those in the history buffer) in the first algorithm step, the positions of the matched substrings of length lₘᵢₙ within the history buffer may be examined. In some instances, the symbols following the matched substrings in the history buffer may be compared with those in the look-ahead buffer, starting from the CP+2+lₘᵢₙ, in an attempt to extend the matches.

Alternatively, or additionally, for each match, the symbols preceding the coding position (CP+2) may be compared with symbols before the matched substrings in the history buffer. Such comparison may help identify potential substring matches corresponding to the coding positions from the DMW=0 iteration and DMW=1 iteration. The possible outcomes may rely on a best match length and the DMW iteration from which the best match may originate (e.g., the winning DMW iteration). Based on the outcomes, the following described decisions may be taken.

In a first decision, in instances in which the best match length is ≥ lₘᵢₙ+2+1, the winning match may come from the DMW=2 iteration. Alternatively, or additionally, if the winning match is from the DMW=1 iteration or the DMW=0 iteration, the substring may also include a match from the DMW=2 iteration. No independent search may be needed for the DMW=0 iteration or the DMW=1 iteration. In such instances, a comparison of the symbols before the matched substring in the DMW=2 iteration may be enough to determine the winning DMW iteration, which may contribute to improving efficiency by reducing a number of calculations performed. The best match may be selected, and the optimal substring may be passed to the next coding stage. In instances in which there is a tie, the match closest to the current coding position may be selected. In instances in which the DMW=0 iteration wins, the result may be output as a <distance, length> pair. In instances in which the DMW=1 iteration or the DMW=2 iteration wins, the resultant output may be a combination of literals and a <distance, length> pair.

In a second decision, in instances in which the best match length is lₘᵢₙ+2 and the winning DMW iteration is the DMW=0 iteration or the DMW=1 iteration, the winning substring may also include a match from the DMW=2 iteration (e.g., of length lₘᵢₙ). In such instances, no independent search may be needed for the DMW=0 iteration or for the DMW=1 iteration. In such instances, a comparison of the symbols before the matched substring positions with those before the coding position (e.g., coding position+2) may be enough to determine if the DMW=0 iteration or the DMW=1 iteration may be the winner over the DMW=2 iteration. In instances in which the DMW=0 iteration wins, the result may be output as a <distance, length> pair. In instances in which the DMW=1 iteration wins, the resultant output may be a combination of literal and a <distance, length> pair.

In instances in which the DMW=2 iteration is the winner, the DMW=1 iteration may not have a winning substring that doesn't contain a match from the DMW=2 iteration.

In such instances, a substring of length lₘᵢₙ+1 can still be the winner in the DMW=0 iteration, even without the DMW=2 iteration match. In such instances, an independent search may be performed in the DMW=0 iteration to check for a possible winning match. In instances in which the DMW=0 iteration is the winning iteration, the resultant output may be a <distance, length=lₘᵢₙ+1> pair. In instances in which the DMW=2 iteration is the winning iteration, the resultant output may be a combination of literals and a <distance, length=lₘᵢₙ+2> pair.

In a third decision, in instances in which the best match length is lₘᵢₙ+1 (e.g., 5), the winning DMW iteration could be the DMW=1 iteration or the DMW=2 iteration. In such instances, the DMW=1 iteration may win over the DMW=2 iteration. In some instances, the DMW=0 iteration may also have a substring match of length lₘᵢₙ+1 that may not include the matches from the DMW=1 iteration and/or the DMW=2 iteration. In such instances, an additional search may be performed for the DMW=0 iteration. In instances in which the DMW=0 iteration is the winning iteration, the resultant output may be a <distance, length> pair. In instances in which the DMW=1 iteration is the winning iteration, the resultant output may be a combination of a literal and a <distance, length> pair.

In a fourth decision, in instances in which the best match length is lₘᵢₙ (e.g., 4), the best match length may be from the DMW=0 iteration, the DMW=1 iteration, and/or the DMW=2 iteration (e.g., refer case ‘e’ in Table 1), where the DMW=0 may win. In such instances, a DMW=0 iteration match of length lₘᵢₙ+1 may still be possible. In such instances, an additional search may be needed for the DMW=0 iteration. A <distance, length>pair of the DMW=0 iteration may be output with length=lₘᵢₙ or lₘᵢₙ+1.

Applying the algorithm as described to a test setup yielded results in which the proposed algorithm improves the latency relative to conventional methods. For example, the LZ77 Encoder may be updated in the XP10 implementation with the proposed algorithm, while keeping rest of the implementation the same. In such configurations, it can be observed that there may be a reduction in latency using the proposed algorithm compared to conventional approaches (e.g., lazy matching using independent LZ77 search in each DMW iteration). In some instances, the latency in the XP10 compression using the proposed algorithm using the DMW=2 iteration may be similar to conventional lazy matching. The results are summarized in Table 2. The proposed algorithm illustrates a decrease in latency when compressing blocks from the widely used Silesia corpus.

TABLE 2
Reduction of latency using proposed lazy matching
algorithm

| | | Proposed | |
|---|---|---|---|
| | Lazy | Lazy | |
| | Matching | Matching | % |
| | with | with | Reduction |
| Data | DMW = 2 | DMW = 2 | of |
| file | (uSeconds) | (uSeconds) | latency |
| Dickens | 17493 | 11502 | 34 |
| Mozilla | 124725 | 73928 | 40 |
| Mr | 39639 | 20539 | 48 |
| Nci | 30115 | 22695 | 24 |
| Ooffice | 21974 | 15843 | 27 |
| Osdb | 7128 | 6092 | 14 |
| Reymont | 36985 | 18141 | 50 |
| Samba | 17268 | 12413 | 28 |
| Sao | 10846 | 8417 | 22 |
| Webster | 13345 | 9169 | 31 |
| Xml | 9375 | 6480 | 30 |
| x-ray | 7556 | 7990 | −6 |

In some instances, increasing the DMW iteration lengths in the lazy matching approach may be useful for achieving higher compression ratios and/or improving storage capacity in storage appliances. In some instances, increasing the DMW iteration length may come with an impact on compression latency and/or computational workload, as the lazy matching algorithms perform multiple LZ77 searches, such as one in each DMW iteration. The algorithm presented herein mitigates the increase in compression latency by eliminating multiple LZ77 searches through backward lazy matching approach. Such algorithm may enable lower compression latency and/or higher throughput and IOPS in storage appliances and software defined storage, while maintaining the high compression ratios associated with the lazy matching approach.

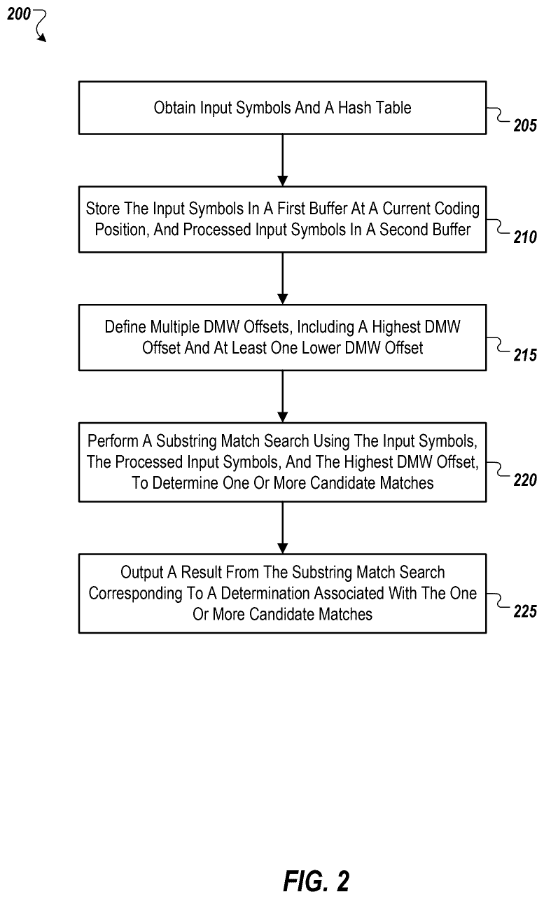

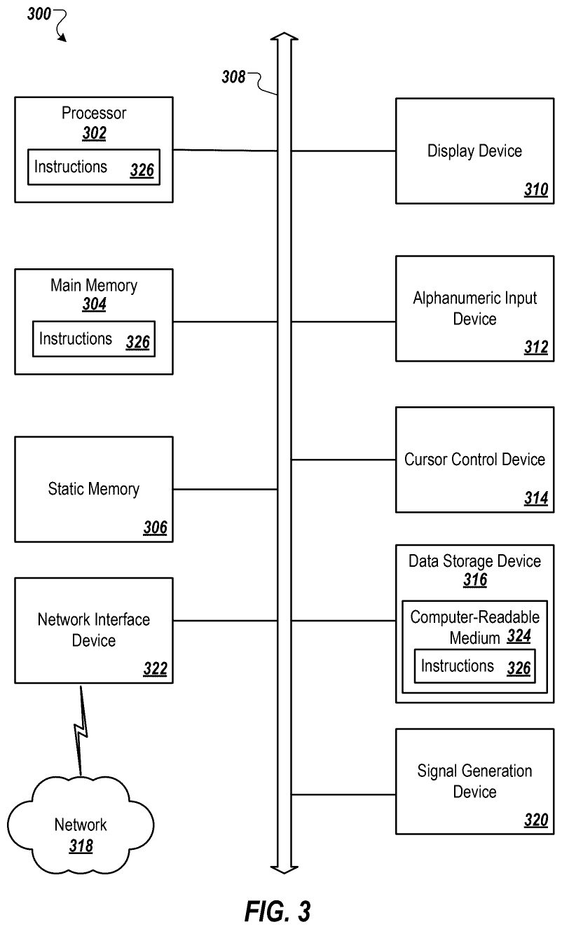

FIG. 2 illustrates a flowchart of an example method 200 for lazy matching with reduced latency for dictionary-based compression. The method 200 may be performed by processing logic that may include hardware (circuitry, dedicated logic, etc.), software (such as is run on a general purpose computer system or a dedicated machine), or a combination of both, which processing logic may be included in any computer system or device such as the computing device 300 of FIG. 3.

For simplicity of explanation, methods described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification may be capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

The method 200 may begin at block 205 where processing logic may obtain input symbols and a hash table. In some instances, the hash table may be configured to associate rolling hash-values of substrings having a minimum match length in the second buffer with one or more positions of corresponding substrings in the second buffer.

At block 210, the processing logic may store the input symbols in a first buffer at a current coding position. Alternatively, or additionally, the processing logic may store processed input symbols in a second buffer. In some instances, the first buffer may be a look-ahead buffer and the second buffer may be a history buffer.

At block 215, the processing logic may define multiple delayed match window (DMW) offsets. The DMW offsets may comprise a highest DMW offset and/or at least one lower DMW offset.

At block 220, the processing logic may perform a substring match search using the input symbols, the processed input symbols, and/or the highest DMW offset, to determine one or more candidate matches. In some instances, the substring match search may begin at the highest DMW offset and may iterate through the multiple DMW offsets.

In some instances, the substring match search may further include computing a rolling hash value for a look-ahead substring beginning at the current coding position plus the highest DMW offset. The substring match search may also include performing a lookup in the hash table using the rolling hash value to obtain one or more candidate match positions. In some instances, the processing logic may extend a match length of each of the one or more candidate match positions by comparing the input symbols following a substring match in the first buffer with the processed input symbols corresponding to the substring match in the second buffer. Alternatively, or additionally, the processing logic may select, from the one or more candidate match positions, a first best match for the highest DMW offset based on an extended match length.

In some instances, the processing logic may compare symbols preceding the look-ahead substring in the first buffer with symbols preceding the substring match in the second buffer to determine a second best match for the at least one lower DMW offset. In some instances, the symbol comparison may be performed without an independent scan of the second buffer.

Alternatively, or additionally, the processing logic may compute a second rolling hash value for a second look-ahead substring. The processing logic may also perform a lookup in the hash table using the second rolling hash value to obtain one or more second candidate match positions. In some instances, the second rolling hash value may be computed based on an extended match length determined for the higher DMW offset and at least one lower DMW offset.

At block 225, the processing logic may output a result from the substring match search corresponding to a determination associated with the one or more candidate matches.

Modifications, additions, or omissions may be made to the method 300 without departing from the scope of the present disclosure. For example, the processing logic may . . . select a winning DMW offset and a corresponding length and distance pair from the plurality of DMW offsets by comparing the one or more candidate matches across the plurality of DMW offsets. In some instances, the result may include one or more literal symbols output to a next coding stage when the winning DMW offset may be the highest DMW offset or a non-zero DMW offset in the plurality of DMW offsets. In some instances, the one or more literal symbols may correspond to DMW-skipped symbols followed by the length and distance pair.

Alternatively, or additionally, the result may include the length and distance pair output to a next coding stage when the winning DMW offset a lowest DMW offset. Alternatively, or additionally, the result may include a literal symbol and no length and distance pair output to a next coding stage when the one or more candidate matches may fail to satisfy a minimum match length. Alternatively, or additionally, the result may include moving one or more literal symbols in the input symbols associated with the winning DMW offset and the length and distance pair to a next coding stage.

In another example, the designations of different elements in the manner described is meant to help explain concepts described herein and is not limiting. Further, the method 200 may include any number of other elements or may be implemented within other systems or contexts than those described.

FIG. 3 illustrates an example computing device 300 within which a set of instructions, for causing the machine to perform any one or more of the methods discussed herein, may be executed. The computing device 300 may include a mobile phone, a smart phone, a netbook computer, a rackmount server, a router computer, a server computer, a personal computer, a mainframe computer, a laptop computer, a tablet computer, a desktop computer, or any computing device with at least one processor, etc., within which a set of instructions, for causing the machine to perform any one or more of the methods discussed herein, may be executed. In alternative implementations, the machine may be connected (e.g., networked) to other machines in a LAN, an intranet, an extranet, or the Internet. The machine may operate in the capacity of a server machine in client-server network environment. The machine may include a personal computer (PC), a set-top box (STB), a server, a network router, switch or bridge, or any machine capable of executing a set of instructions (sequential or otherwise) that specify actions to be taken by that machine. Further, while only a single machine is illustrated, the term “machine” may also include any collection of machines that individually or jointly execute a set (or multiple sets) of instructions to perform any one or more of the methods discussed herein.

The computing device 300 includes a processing device 302 (e.g., a processor), a main memory 304 (e.g., read-only memory (ROM), flash memory, dynamic random access memory (DRAM) such as synchronous DRAM (SDRAM)), a static memory 306 (e.g., flash memory, static random access memory (SRAM)) and a data storage device 316, which communicate with each other via a bus 308.

The processing device 302 represents one or more general-purpose processing devices such as a microprocessor, central processing unit, or the like. More particularly, the processing device 302 may include a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device 302 may also include one or more special-purpose processing devices such as an application specific integrated circuit (ASIC), a field programmable gate array (FPGA), a digital signal processor (DSP), network processor, or the like. The processing device 302 is configured to execute instructions 326 for performing the operations and steps discussed herein.

The computing device 300 may further include a network interface device 322 which may communicate with a network 318. The computing device 300 also may include a display device 310 (e.g., a liquid crystal display (LCD) or a cathode ray tube (CRT)), an alphanumeric input device 312 (e.g., a keyboard), a cursor control device 314 (e.g., a mouse) and a signal generation device 320 (e.g., a speaker). In at least one implementation, the display device 310, the alphanumeric input device 312, and the cursor control device 314 may be combined into a single component or device (e.g., an LCD touch screen).

The data storage device 316 may include a computer-readable storage medium 324 on which is stored one or more sets of instructions 326 embodying any one or more of the methods or functions described herein. The instructions 326 may also reside, completely or at least partially, within the main memory 304 and/or within the processing device 302 during execution thereof by the computing device 300, the main memory 304 and the processing device 302 also constituting computer-readable media. The instructions may further be transmitted or received over a network 318 via the network interface device 322.

While the computer-readable storage medium 324 is shown in an example implementation to be a single medium, the term “computer-readable storage medium” may include a single medium or multiple media (e.g., a centralized or distributed database and/or associated caches and servers) that store the one or more sets of instructions. The term “computer-readable storage medium” may also include any medium that is capable of storing, encoding or carrying a set of instructions for execution by the machine and that cause the machine to perform any one or more of the methods of the present disclosure. The term “computer-readable storage medium” may accordingly be taken to include, but not be limited to, solid-state memories, optical media and magnetic media.

A number of implementations have been described. Nevertheless, it will be understood that various modifications may be made without departing from the spirit and scope of the disclosure. Accordingly, other implementations are within the scope of the following claims.

In accordance with common practice, the various features illustrated in the drawings may not be drawn to scale. The illustrations presented in the present disclosure are not meant to be actual views of any particular apparatus (e.g., device, system, etc.) or method, but are merely idealized representations that are employed to describe various embodiments of the disclosure. Accordingly, the dimensions of the various features may be arbitrarily expanded or reduced for clarity. In addition, some of the drawings may be simplified for clarity. Thus, the drawings may not depict all of the components of a given apparatus (e.g., device) or all operations of a particular method.

Terms used herein and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, it is understood that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc. For example, the use of the term “and/or” is intended to be construed in this manner.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms first,” “second,” “third,” etc., connote a specific number of elements, these terms should not be understood to connote a specific number of elements. For example, a first widget may be described as having a first side and a second widget may be described as having a second side. The use of the term “second side” with respect to the second widget may be to distinguish such side of the second widget from the “first side” of the first widget and not to connote that the second widget has two sides.

All examples and conditional language recited herein are intended for pedagogical objects to aid the reader in understanding the invention and the concepts contributed by the inventor to furthering the art, and are to be construed as being without limitation to such specifically recited examples and conditions. Although embodiments of the present disclosure have been described in detail, it should be understood that the various changes, substitutions, and alterations could be made hereto without departing from the spirit and scope of the present disclosure.

What is claimed is:

1. A method of dictionary-based lossless data compression, comprising:
obtaining input symbols and a hash table;
storing the input symbols in a first buffer at a current coding position, and processed input symbols in a second buffer;
defining a plurality of delayed match window (DMW) offsets, comprising a highest DMW offset and at least one lower DMW offset;
performing a substring match search using the input symbols, the processed input symbols, and the highest DMW offset, to determine one or more candidate matches; and
outputting a result from the substring match search corresponding to a determination associated with the one or more candidate matches.

2. The method of claim 1, wherein the substring match search begins at the highest DMW offset and iterates through the plurality of DMW offsets.

3. The method of claim 1, wherein the substring match search further comprises:
computing a rolling hash value for a look-ahead substring beginning at the current coding position plus the highest DMW offset; and
performing a lookup in the hash table using the rolling hash value to obtain one or more candidate match positions.

4. The method of claim 3, further comprising extending a match length of each of the one or more candidate match positions by comparing the input symbols following a substring match in the first buffer with the processed input symbols corresponding to the substring match in the second buffer.

5. The method of claim 4, further comprising selecting, from the one or more candidate match positions, a first best match for the highest DMW offset based on an extended match length.

6. The method of claim 4, further comprising comparing symbols preceding the look-ahead substring in the first buffer with symbols preceding the substring match in the second buffer to determine a second best match for the at least one lower DMW offset.

7. The method of claim 6, wherein the symbol comparison is performed without an independent scan of the second buffer.

8. The method of claim 3, further comprising:
computing a second rolling hash value for a second look-ahead substring;
performing a lookup in the hash table using the second rolling hash value to obtain one or more second candidate match positions.

9. The method of claim 8, wherein the second rolling hash value is computed based on an extended match length determined for the higher DMW offset and at least one lower DMW offset.

10. The method of claim 1, further comprising selecting a winning DMW offset and a corresponding length and distance pair from the plurality of DMW offsets by comparing the one or more candidate matches across the plurality of DMW offsets.

11. The method of claim 10, wherein the result comprises one or more literal symbols output to a next coding stage when the winning DMW offset is the highest DMW offset or a non-zero DMW offset in the plurality of DMW offsets.

12. The method of claim 11, wherein the one or more literal symbols correspond to DMW-skipped symbols followed by the length and distance pair.

13. The method of claim 10, wherein the result comprises the length and distance pair output to a next coding stage when the winning DMW offset a lowest DMW offset.

14. The method of claim 10, wherein the result comprises a literal symbol and no length and distance pair output to a next coding stage when the one or more candidate matches fail to satisfy a minimum match length.

15. The method of claim 10, wherein the result comprises moving one or more literal symbols in the input symbols associated with the winning DMW offset and the length and distance pair to a next coding stage.

16. The method of claim 1, wherein the hash table is configured to associate rolling hash-values of substrings having a minimum match length in the second buffer with one or more positions of corresponding substrings in the second buffer.

17. The method of claim 1, wherein the first buffer is a look-ahead buffer and the second buffer is a history buffer.

18. A computing system, comprising:
a processor;
a memory storing instructions that, when executed by the processor, cause the computing system to:
obtain input symbols and a hash table;
store the input symbols in a first buffer at a current coding position, and processed input symbols in a second buffer;
define a plurality of delayed match window (DMW) offsets, comprising a highest DMW offset and at least one lower DMW offset;
perform a substring match search using the input symbols, the processed input symbols, and the highest DMW offset, to determine one or more candidate matches; and
output a result from the substring match search corresponding to a determination associated with the one or more candidate matches.

19. The computing system of claim 18, wherein the substring match search further comprises:
compute a rolling hash value for a look-ahead substring beginning at the current coding position plus the highest DMW; and
perform a lookup in the hash table using the rolling hash value to obtain one or more candidate match positions.

20. The computing system of claim 19, further comprising:
extend a match length of each of the one or more candidate match positions by comparing the input symbols following a substring match in the first buffer with the processed input symbols corresponding to the substring match in the second buffer; and
compare symbols preceding the look-ahead substring in the first buffer with symbols preceding the substring match in the second buffer to determine a second best match for the at least one lower DMW offset.
